(19) United States
(12) Patent Application Publication
(10) Pub. No.: US 2022/0136106 A1
(43) Pub. Date: May 5, 2022

(54) ADVANCED PRECURSORS FOR SELECTIVE ATOMIC LAYER DEPOSITION USING SELF-ASSEMBLED MONOLAYERS

(71) Applicant: The Board of Trustees of the Leland Stanford Junior University, Palo Alto, CA (US)

(72) Inventors: Il-Kwon Oh, Suwon (KR); Stacey F. Bent, Stanford, CA (US)

(21) Appl. No.: 17/516,139

(22) Filed: Nov. 1, 2021

Related U.S. Application Data
(60) Provisional application No. 63/107,930, filed on Oct. 30, 2020.

(51) Int. Cl. C23C 16/455; H01L 21/02; C23C 16/40

(52) U.S. Cl. CPC C23C 16/45553; H01L 21/02178; C23C 16/403; H01L 21/0228; H01L 21/02205

(57) ABSTRACT

Advanced precursors for selective atomic layer deposition (ALD) of aluminum oxide (Al₂O₃) using self-assembled monolayers (SAM) are provided. Area selective atomic layer deposition (AS-ALD) is a highly sought-after strategy for the fabrication of next-generation electronics. Embodiments described herein provide a process of selective ALD of Al₂O₃ that achieves an excellent selectivity between an SAM-coated surface and non-coated surface by adopting one of several novel ALD precursors. Some embodiments further optimize process parameters (e.g., growth temperature, precursor partial pressure, precursor dosing time, purging time, reactant dosing time, and number of cycles) to further improve selectivity of the ALD precursor.

### RELATED APPLICATIONS

This application claims the benefit of provisional patent application Ser. No. 63/107,930, filed Oct. 30, 2020, the disclosure of which is hereby incorporated herein by reference in its entirety.

### GOVERNMENT SUPPORT

This invention was made with government support under NIST Award No 70NANB17H041 (NIST is the National Institute of Standards and Technology, a unit of the U.S. Commerce Department). The government has certain rights in the invention.

### FIELD OF THE DISCLOSURE

The present disclosure is related to atomic layer deposition (ALD) for electronic device fabrication.

### BACKGROUND

Area-selective atomic layer deposition (AS-ALD) is a bottom-up fabrication process that employs surface chemistry to deposit thin-film material in a targeted area while maintaining large area uniformity, excellent conformality, and angstrom-level thickness control. Therefore, it can enable a reduction in the number of lithography and etch steps and in the use of toxic reagents during the patterning process for electronic device fabrication, resulting in a decrease of edge placement errors as well as a drop in manufacturing costs.

Both standard atomic layer deposition (ALD) and AS-ALD processes are strongly dependent on the ALD chemistry used. For example, some ALD systems, such as titanium oxide (TiO₂), exhibit different nucleation behavior depending on both the titanium (Ti) precursor and the substrate for a given process temperature. This observation suggests the importance of selecting the right precursor for a given ALD process. Precursor design is likely to be even more important in AS-ALD processes, for which there are numerous examples of selectivity strategies (e.g., self-assembled monolayers (SAMs)) that work well for one ALD process but not another.

The types of precursors studied for AS-ALD are broadly distributed, including alkyls, halides, amidinates, cyclopentadienyls, β-diketonates, alkoxides, and heteroleptic precursor systems. The metal alkyls such as trimethylaluminum (Al(CH₃)₃, also referred to as TMA) and diethylzinc (Zn(C₂H₅)₂, also referred to as DEZ) have been among the most widely used for ALD because they are efficiently delivered to ALD reactors due to their high vapor pressure. They are also highly reactive, providing a robust thermodynamic favorability of adsorption on the surface. To block this adsorption for AS-ALD, most of the work on aluminum oxide (Al₂O₃) and zinc oxide (ZnO) has used inhibition layers such as SAMs. However, commonly when using the TMA precursor with SAMs, TMA adsorbs on or within the SAM after a few tens of cycles, leading to selectivity loss, and thus this popular ALD precursor is challenging to use in AS-ALD. In terms of growth inhibition, DEZ has been shown to be superior to TMA in some systems; for example, the blocking selectivity of Al₂O₃ is limited to only ˜6 nanometers (nm), whereas ZnO is blocked for over ˜30 nm on the same SAM surface. This difference can be attributed to precursor chemistry, which motivates the need to understand the mechanism of AS-ALD based on precursor properties.

### SUMMARY

Advanced precursors for selective atomic layer deposition (ALD) using self-assembled monolayers (SAM) are provided. Area-selective atomic layer deposition (AS-ALD) is a highly sought-after strategy for the fabrication of next-generation electronics. Embodiments described herein provide a process of selective ALD that achieves an excellent selectivity between an SAM-coated surface and non-coated surface by adopting one of several novel ALD precursors. Key precursor design parameters strongly influence the efficacy of AS-ALD, as demonstrated herein by comparing a series of precursors having the same metal center but different ligands. Some embodiments further optimize process parameters (e.g., growth temperature, precursor partial pressure, precursor dosing time, purging time, reactant dosing time, and number of cycles) to further improve selectivity of the ALD precursor.

As an example, for AS-ALD of aluminum oxide (Al₂O₃) the effect of precursor chemistry (reactivity and molecular size) on ALD selectivity is demonstrated when a number of methyl and chloride groups in Al(CH₃)ₓCl₃₋ₓ (x=0, 2, and 3) and the chain length of alkyl ligands in AlC_{y}H_{2y+1} (y=1 and 2) are changed. The results show that optimized parameters for the Al₂O₃ALD processes on an SAM-terminated substrate, which serves as the nongrowth surface, differ significantly from those on a silicon (Si) substrate. Chlorine-containing precursors need a much longer purging time on the SAMs because of a stronger Lewis acidity compared to that of alkyl precursors. With reoptimized conditions, the ALD of Al₂O₃ using the Al(C₂H₅)₃ precursor is blocked most effectively by SAM inhibitors, whereas the widely employed Al(CH₃)₃ precursor is blocked least effectively among the precursors tested.

Finally, evaluation results show that a selectivity exceeding 0.98 is achieved for up to 75 ALD cycles with Al(C₂H₅)₃, for which 6 nanometers (nm) of Al₂O₃ film grows selectively on silicon dioxide (SiO₂)-covered Si. Propensity to form dimers varies across the aluminum (Al) precursors, with the more Lewis acidic Al chloride precursors more likely to be in the dimer form at the ALD temperatures than the alkyl precursors. A combination of precursor reactivity and effective molecular size affects the blocking of the different precursors, explaining why Al(C₂H₅)₃, with weaker Lewis acidity and relatively large size, exhibits the best blocking results.

An exemplary embodiment provides a method for selective ALD. The method includes applying an ALD precursor to a substrate, wherein an effective average molecule size (V_{eff}) of the ALD precursor is greater than 100 cubic angstroms (Å³) and effective average molecule size is defined as

$${V}_{eff} = \frac{{C}_{m o n o m e r} {V}_{m o n o m e r} + {C}_{d i m e r} {V}_{d i m e r}}{{C}_{m o n o m e r} + {C}_{d i m e r}}$$

where Cₘₒₙₒₘₑᵣ is a fractional concentration of a monomer of the ALD precursor, C_{dimer} is a fractional concentration of a dimer of the ALD precursor, Vₘₒₙₒₘₑᵣ is a van der Waal (VDW) size of the monomer, and V_{dimer} is a VDW size of the dimer. The method further includes performing selective ALD of a deposition material over the substrate.

Another exemplary embodiment provides a method for selective ALD. The method includes applying an ALD precursor to a substrate, wherein the ALD precursor comprises an aluminum alkyl chloride compound (Al(C_{y}H_{2y+1})ₓCl₃₋ₓ, where 0≤x≤2 and y≥1), an aluminum alkyl compound (Al(C_{y}H_{2y+1})₃, where y≥2), an aluminum alkyl alkoxide (Al(CₙH₂ₙ₊₁)₃₋ₓ(OC_{z}H_{2z+1})ₓ, where 1≤x≤3, z≥2, and n≥1), or an aluminum precursor containing a cyclopentadienyl (Cp) ligand. The method further includes performing selective ALD of a deposition material over the substrate.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a graphical representation of growth per cycle (GPC) of atomic layer deposition (ALD) aluminum oxide (Al₂O₃) films using Al(CH₃)ₓCl₃₋ₓ (where x=0, 2, and 3) as a function of precursor exposure at 200° C.

FIG. 1B is a graphical representation of GPC of ALD Al₂O₃ films using Al(C_{y}H_{2y+1})₃ (where y=1 and 2) as a function of precursor exposure at 200° C.

FIG. 2 is a graphical representation of change in water contact angle (WCA) with increasing number of ALD Al₂O₃ cycles on a self-assembled monolayer (SAM)-coated surface using Al(CH₃)ₓCl₃₋ₓ (x=0, 2, and 3) and Al(C_{y}H_{2y+1})₃ (y=1 and 2) precursors.

FIG. 3A is a graphical representation of normalized aluminum (Al) composition represented as Al/(Al+Si) percentage on the SAM-coated surface as a function of ALD cycle numbers for the four Al precursors with normal ALD process (shorter purging time).

FIG. 3B is a graphical representation of the amount of Al deposited on the SAM-coated surface as a function of purging time at a fixed cycle-number of 50 cycles.

FIG. 3C is a graphical representation of the amount of Al deposited using optimized conditions for ALD on the SAM-coated surface as a function of ALD cycle numbers for the four Al precursors.

FIG. 4 is a graphical representation of growth per cycle of Al₂O₃ with Al(CH₃)ₓCl₃₋ₓ (x=0, 1, and 3) as a function of precursor purging time on silicon (Si).

FIG. 5A is a graphical representation of Al atomic percentage defined as Al/(Al+Si) and Al/(Al+Au) for ALD from AlCl₃ on 1-Octadecanethiol (ODT)/gold (Au) and octadecyltrichlorosilane (ODTS)/Si, respectively, with increasing ALD cycle number.

FIG. 5B is a graphical representation of Al atomic percentage for ALD from Al(CH₃)₃ on ODT/Au and ODTS/Si with increasing ALD cycle number.

FIG. 6A is a graphical representation of the selectivity of Al₂O₃ALD on Si compared to that on the SAM-coated surface as a function of the number of ALD cycles.

FIG. 6B is a graphical representation of the selectivity of Al₂O₃ALD replotted as a function of equivalent thickness on a Si surface (growth surface, GS).

FIG. 7 is a graphical representation of the van der Waals (VDW) volumes of the monomeric and dimeric structures of Al(CH₃)ₓCl₃₋ₓ (where x=0, 1, 2, and 3) and Al(C_{y}H_{2y+1})₃ (where y=1 and 2).

FIG. 8A is a scanning electron microscopy (SEM) image of an Al₂O₃ pattern fabricated by 50 cycles of AS-ALD on an ODTS-treated platinum(Pt)/silicon dioxide (SiO₂) substrate.

FIG. 8B is a graphical representation of elemental line spectra for carbon, silicon, aluminum, and platinum along the vertical dashed line of FIG. 8A.

FIG. 8C is an elemental mapping of Auger electron spectroscopy (AES) for carbon (C) in the Al₂O₃ pattern on the ODTS-treated Pt/SiO₂ of FIG. 8A.

FIG. 8D is an elemental mapping of AES for Si in the Al₂O₃ pattern on the ODTS-treated Pt/SiO₂ of FIG. 8A.

FIG. 8E is an elemental mapping of AES for Al in the Al₂O₃ pattern on the ODTS-treated Pt/SiO₂ of FIG. 8A.

FIG. 8F is an elemental mapping of AES for Pt in the Al₂O₃ pattern on the ODTS-treated Pt/SiO₂ of FIG. 8A.

FIG. 9 is a flow diagram illustrating a process for selective ALD.

FIG. 10 is a flow diagram illustrating another process for selective ALD.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Advanced precursors for selective atomic layer deposition (ALD) using self-assembled monolayers (SAM) are provided. Area-selective atomic layer deposition (AS-ALD) is a highly sought-after strategy for the fabrication of next-generation electronics. Embodiments described herein provide a process of selective ALD that achieves an excellent selectivity between an SAM-coated surface and non-coated surface by adopting one of several novel ALD precursors. Key precursor design parameters strongly influence the efficacy of AS-ALD, as demonstrated herein by comparing a series of precursors having the same metal center but different ligands. Some embodiments further optimize process parameters (e.g., growth temperature, precursor partial pressure, precursor dosing time, purging time, reactant dosing time, and number of cycles) to further improve selectivity of the ALD precursor.

As an example, for AS-ALD of aluminum oxide (Al₂O₃) the effect of precursor chemistry (reactivity and molecular size) on ALD selectivity is demonstrated when a number of methyl and chloride groups in Al(CH₃)ₓCl₃₋ₓ (x=0, 2, and 3) and the chain length of alkyl ligands in AlC_{y}H_{2y+1} (y=1 and 2) are changed. The results show that optimized parameters for the Al₂O₃ALD processes on an SAM-terminated substrate, which serves as the nongrowth surface, differ significantly from those on a silicon (Si) substrate. Chlorine-containing precursors need a much longer purging time on the SAMs because of a stronger Lewis acidity compared to that of alkyl precursors. With reoptimized conditions, the ALD of Al₂O₃ using the Al(C₂H₅)₃ precursor is blocked most effectively by SAM inhibitors, whereas the widely employed Al(CH₃)₃ precursor is blocked least effectively among the precursors tested.

Finally, evaluation results show that a selectivity exceeding 0.98 is achieved for up to 75 ALD cycles with Al(C₂H₅)₃, for which 6 nanometers (nm) of Al₂O₃ film grows selectively on silicon dioxide (SiO₂)-covered Si. Quantum chemical calculations show significant differences in the energetics of dimer formation across the example Al precursors, with only ˜1% of AlCl₃ and Al(CH₃)₂Cl precursors but 99% of the alkyl precursors, Al(CH₃)₃ and Al(C₂H₅)₃, existing as monomers at 200° C. A combination of precursor reactivity and effective molecular size affects the blocking of the different precursors, explaining why Al(C₂H₅)₃, with weaker Lewis acidity and relatively large size, exhibits the best blocking results.

I. Introduction

The present disclosure studies how precursor design influences AS-ALD with SAM inhibitors. A comparative study is carried out for a series of aluminum (Al) precursors—Al(CH₃)ₓCl₃₋ₓ and Al(C_{y}H_{2y+1})₃—which contain the same Al metal center but different ligands. These precursors vary in their properties, such as reactivity and molecular size. For instance, precursors in the series Al(CH₃)ₓCl₃₋ₓ (where x=0, 2, and 3) have different reactivities but similar monomeric sizes, whereas those of Al(C_{y}H_{2y+1})₃ (where y=1 and 2) have different monomeric sizes but similar reactivities.

Based on this systematic study, embodiments provide improved AS-ALD using advanced precursors by determining the role of the precursor design on important AS-ALD parameters, such as nucleation, blocking ability, and selectivity. For example, the presence of chloride ligands in the Al precursor necessitates much longer purging times during ALD cycles to avoid unwanted Al₂O₃ deposition on SAM-protected surfaces. As another example, the Al(C₂H₅)₃ precursor is blocked most effectively by SAM inhibitors while the widely employed Al(CH₃)₃ precursor is blocked most poorly.

In this regard, the improved AS-ALD process can be extended to many different deposition materials, including but not limited to metal chalcogenides (e.g., oxides, tellurides, sulfides, selenides, etc.), metal pnictides (e.g., nitrides, phosphides, etc.), metal halides (e.g., chlorides, bromides, iodides, etc.), and metal-group 14 compounds (e.g., carbides, silicides, germanides, etc.). It is found herein that the use of precursors with a larger effective average molecule size (V_{eff}, described further below) than traditional precursors improves AS-ALD. Thus, in one aspect the advanced precursors used for the improved AS-ALD process have a V_{eff} greater than 100 cubic angstroms (Å³). In further embodiments, the V_{eff} of the advanced precursors may be between 100 Å³ and 300 Å³, between 120 Å³ and 260 Å³, or between 130 Å³ and 200 Å³. The advanced precursors may further depend on the deposition materials and environmental characteristics.

For example, embodiments described herein deploy one of several novel ALD precursors to achieve high selectivity in Al₂O₃ deposition over a substrate. The novel ALD precursors (e.g., for Al-based materials) can include an aluminum alkyl chloride compound (Al(C_{y}H_{2y+1})ₓCl₃₋ₓ, where 0≤x≤2 and y≥1), an aluminum alkyl compound (Al(C_{y}H_{2y+1})₃, where y≥2), or an aluminum alkyl alkoxide compound (Al(CₙH₂ₙ₊₁)₃₋ₓ(OC_{z}H_{2z+1})ₓ, where 1≤x≤3, z≥2, and n≥1), or an aluminum precursor containing a cyclopentadienyl (Cp) ligand. Example precursor compounds include TEA, trichloroaluminum (AlCl₃, also referred to as TCA), dimethylaluminum chloride (Al(CH₃)₂Cl, also referred to as DMACl), and trimethylaluminum (Al(CH₃)₃, also referred to as TMA).

For illustrative purposes, some examples are described below with respect to ALD over a Si substrate with an organosilicon SAM, such as octadecyltrichlorosilane (ODTS). It should be understood that any metal or dielectric material may be used as a substrate, with any appropriate SAM. Example SAM materials include organosilicon compounds (e.g., octadecyltrichlorosilane, octadecyltrimethoxysilane, benzyltrichlorosilane, bromotrimethylsilane, chlorotrimethylsilane, decyltrichlorosilane, dimethyldichlorosilane, hexadecyltrichlorosilane, iodotrimethylsilane, iso-butyltrichlorosilane, methyltrichlorosilane, methyl-10-(trichlorosilyl)decanoate, N-butyltrichlorosilane, octyltrichlorosilane, tert-butyltrichlorosilane, tetrahydrooctyltrichlorosilane, octadecylsiloxane, trimethylsilane), organosulfur compounds (e.g., 11-mercapto-1-undecanol, 1-octadecanethiol, 1-dodecanethiol), alkyl compounds (e.g., 1-decene, 1-decyne, 1-dodecene, 1-dodecyne, 1-hexadecene, 1-octadecene, 1-octene, 1-octyne, 1-tetradecene), a phosphonic acid compound (e.g., octadecylphosphonic acid, 11-hydroxyundecylphosphonic acid), or a polymer compound (e.g., hexamethyldisilazane, hexafluoroisopropyl alcohol, polyhydroxystyrene, polymethacrylamide, poly(methyl methacrylate), polystyrene, poly(tert-butyl methacrylate), polyvinylpyrrolidone).

Finally, evaluations show that a selectivity exceeding 0.98 is achieved for up to 75 ALD cycles with TEA, for which 6 nm of Al₂O₃ film grows selectively on a silicon oxide covered Si growth surface. By pursuing the design of AS-ALD processes and ALD precursors, embodiments described herein provide new methods for additive nanoscale patterning.

It is demonstrated herein that the selective ALD process using these advanced precursors results in improved selectivity when process parameters are optimized. However, the optimized conditions for selective ALD are very different from those for traditional ALD processes. Because of different mechanisms at play between regular ALD and selective ALD, for which nucleation must be inhibited on the nongrowth surface, embodiments described herein modify and improve on existing development technologies of ALD processes.

II. Evaluation Setup

For some evaluations conducted herein, octadecyltrichlorosilane (ODTS; 97%, Sigma-Aldrich) is used as a SAM and anhydrous toluene (99.8%, Sigma-Aldrich) was used as a solvent. Prior to SAM coating, p-doped Si substrates were sonicated for 10 minutes in acetone followed by 10 minutes in isopropanol to strip away organic contaminants and then dried under flowing nitrogen. All Si substrates were covered with SiO₂. The samples were subsequently exposed to a 15-minute ultraviolet (UV)/ozone clean to remove any remaining organic residue as well as to produce a high concentration of surface hydroxyl groups. After wet and dry cleaning, the samples were immediately transferred to a glass vial for the SAM deposition process. They were immersed in a 1 millimolar (mM) solution of ODTS in anhydrous toluene for 48 hours at room temperature. After SAM deposition, the samples were rinsed thoroughly in anhydrous toluene to remove physisorbed material and then dried under flowing nitrogen. Patterned substrates of Pt/SiO₂ were used for the fabrication of Al₂O₃ patterns. 100 nm thick Pt films were formed on a SiO₂/Si substrate by using thermal evaporation, and Pt patterns were fabricated by a photolithography process. These Pt/SiO₂ patterns were coated with ODTS SAMs under the same procedure as described above.

In addition, for a comparative study on the substrate effect, gold (Au) substrates were examined. To form a SAM on Au, 1-Octadecanethiol (ODT; 97%, Sigma-Aldrich) with anhydrous toluene (99.8%, Sigma-Aldrich) as a solvent were used. Prior to SAM coating, Au substrates were cleaned with the same procedure as the Si substrate (sonicated for 10 minutes in acetone followed by 10 minutes in isopropanol). After wet cleaning, the Au samples were coated with ODT SAMs by immersing in a 1 mM solution of ODT in anhydrous toluene in a glass vial for 48 hours at room temperature. As described above, the Si substrate/ODTS SAM and Au substrate/ODT SAM were used for illustrative purposes, and embodiments can include any metal or dielectric non-growth substrate with an organosilicon, organosulfur, alkyl, phosphonic acid, polymer, or other appropriate SAM coating.

The ODTS-coated or ODT-coated substrates, along with Si samples cleaned with the same wet and dry processes, were transferred to a homemade ALD reactor. Al₂O₃ALD processes were performed using trichloroaluminum (TCA; AlCl₃) (Sigma-Aldrich, 99%), dimethylaluminum chloride (DMACl; Al(CH₃)₂Cl) (Sigma-Aldrich, 97%), trimethylaluminum (TMA) (Sigma-Aldrich, 97%), or triethylaluminum (TEA; Al(C₂H₅)₃) (Sigma-Aldrich, 97%) as the precursor, and deionized water was used as a counter reactant at 200° C. Al precursors, individually contained in direct-port delivery vessels, were maintained at room temperature for Al(CH₃)₃ and Al(CH₃)₂Cl, 100° C. for AlCl₃, and 90° C. for Al(C₂H₅)₃, to maintain sufficient vapor pressure for delivery to the ALD reactor. Base pressures of the four precursors in the ALD reactor were measured without N₂ flow. They were maintained in a similar range from 130-160 milliTorr (mTorr) using adjustable needle valves, which is a minimal pressure range controllable in the ALD reactor used, under pumping from a rotary vane pump. Working pressure during the ALD process was maintained at about 500 mTorr under 5 standard cubic centimeters per minute (sccm) of flowing N₂. For a parallel comparison of growth characteristics of the four Al precursors, units of precursor exposure (Torr·s), i.e., the peak of the base pressure of the precursor multiplied by the exposure time, are employed.

Following ALD, samples were characterized ex-situ. Water contact angle (WCA) goniometry measurement was performed with an FTA200 unit (First Ten Angstroms Co.) as a preliminary means of confirming SAM deposition; ˜5 microliters (μL) of a water droplet was used. Film thicknesses on a Si substrate with native oxide were modeled in Woollam Co. CompleteEASE software using a general oscillator layer model containing a Tauc-Lorentz and a Gaussian absorption component with layer models of the native oxide and silicon substrate. The chemical composition of films on the surface was measured by X-ray photoelectron spectroscopy (XPS; PHI VersaProbe III scanning microprobe, PHI Co.) with a monochromatized Al Kα radiation source, operated in high-power mode at 100 watts (W) and 20 kilovolts (kV) with an X-ray beam diameter of 100 microns (μm). Scanning electron microscopy (SEM) and Auger electron spectroscopy (AES) mapping were conducted on a PHI 700 scanning Auger nanoprobe system with an electron beam energy of 10 kiloelectron-volts (keV). The van der Waals (VDW) volumes of the precursor molecules were calculated by Marvin software.

III. Results and Discussion

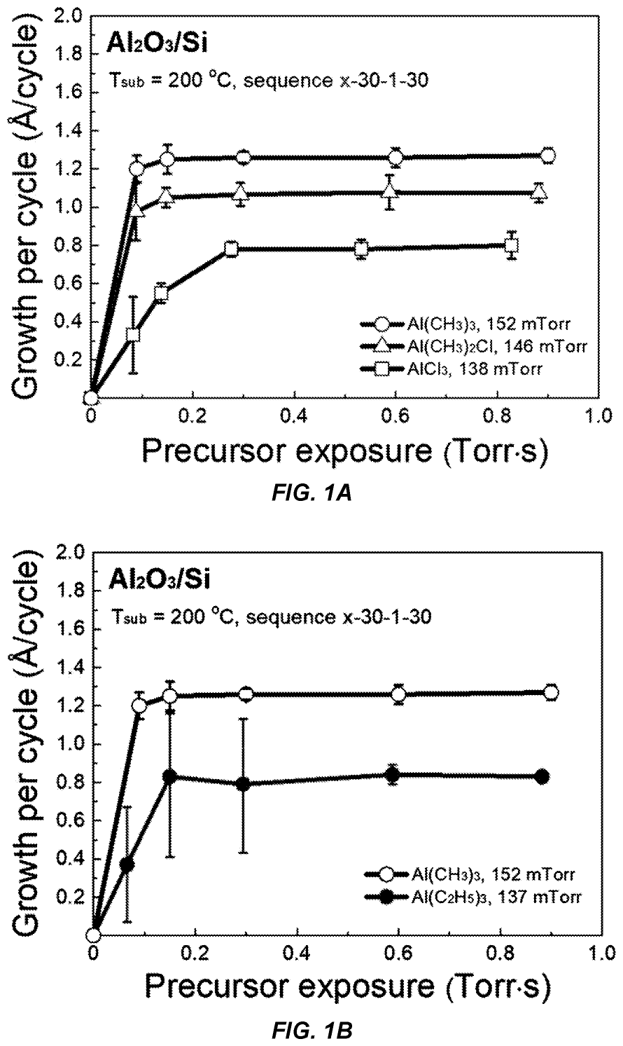

FIG. 1A is a graphical representation of growth per cycle (GPC) of ALD Al₂O₃ films using Al(CH₃)ₓCl₃₋ₓ (where x=0, 2, and 3) as a function of precursor exposure at 200° C. Error bars represent 1 standard deviation across four or five samples. For comparison, the exposure time of H₂O is fixed at 1 second (s) and the purging time of all three precursors at 30 s while changing the precursor exposure. All three Al precursors exhibit saturation of GPC when the precursor exposure is increased. The saturated GPCs are 1.2, 1.0, and 0.8 Å/cycle for Al(CH₃)₃, Al(CH₃)₂Cl, and AlCl₃, respectively, corresponding to previous reports. Saturation of GPC is a growth characteristic typical of ALD, indicating that the precursors undergo self-limited surface reaction and are suitable for the ALD process. Exposures required to reach saturation are found to be 0.07 Torr·s for Al(CH₃)₃ and Al(CH₃)₂Cl, and below 0.14 Torr·s for AlCl₃.

FIG. 1B is a graphical representation of GPC of ALD Al₂O₃ films using Al(C_{y}H_{2y+1})₃ (where y=1 and 2) as a function of precursor exposure at 200° C. GPC saturation occurs by 0.07 Torr·s of precursor exposure for both the Al(CH₃)₃ and Al(C₂H₅)₃ cases. The saturated GPC for Al(C₂H₅)₃ is about 0.8 Å/cycle, which is lower than that for Al(CH₃)₃. The different growth characteristics of Al₂O₃ observed using different precursors indicate that the surface reaction is governed by precursor chemistry, for example, steric hindrance and reactivity. For the following experiments, precursor dose times of 1 s for AlCH₃, Al(CH₃)₂Cl, and Al(C₂H₅)₃ and 2 s for AlCl₃ are used, which are the minimal dose times required for exposure saturation.

For investigation of the blocking properties of Al₂O₃, ODTS SAMs are deposited on the Si substrate. ALD processes on both ODTS/Si and Si substrates are performed using Al(CH₃)ₓCl₃₋ₓ (where x=0, 2, and 3) and Al(C_{y}H_{2y+1})₃ (where y=1 and 2) precursors combined with water as a counter reactant, under the same process conditions as obtained on Si substrates shown in FIG. 1A.

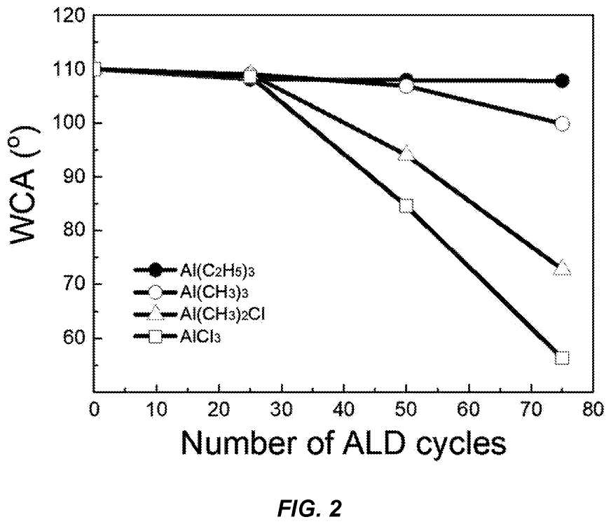

FIG. 2 is a graphical representation of change in WCA with increasing number of ALD Al₂O₃ cycles on a SAM-coated surface (here, an ODTS-coated Si substrate) using Al(CH₃)ₓCl₃₋ₓ (x=0, 2, and 3) and Al(C_{y}H_{2y+1})₃ (y=1 and 2) precursors. At 0 cycles, the WCA value is 110°, indicating that the prepared SAM is well packed on the Si surface. After 25 cycles, the WCA decreases only slightly by about 2-3° for all four precursors, indicative that the SAM layer is still preserved. However, after 50 cycles, the WCA decreases more appreciably, and the rate of change is very different for each precursor. The significant drop in WCA after 50 cycles is attributed to the growth of hydrophilic Al₂O₃ layers on the SAM-coated surface. Some noteworthy trends are evident in the WCA data. For the Al(CH₃)ₓCl₃₋ₓ precursor series, as the number of Cl ligands of the precursor is increased, a more significant decrease is observed in the WCA, indicating a relative increase in the formation of Al₂O₃ layers by the more chlorinated precursors. For Al(C_{y}H_{2y+1})₃, the shorter chain length Al(CH₃)₃ precursor shows a larger decrease in WCA values compared to Al(C₂H₅)₃.

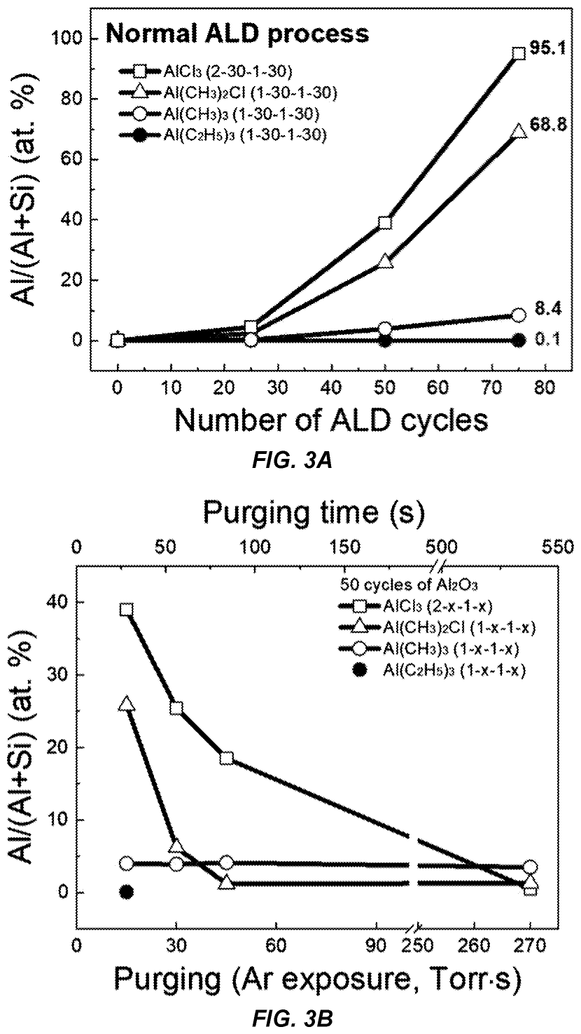

FIGS. 3A-3C illustrate blocking properties of Al₂O₃ on ODTS SAMs. To determine the chemical composition of the surface after ALD, XPS analysis is performed. FIG. 3A is a graphical representation of normalized Al composition represented as Al/(Al+Si) percentage on the SAM-coated surface as a function of ALD cycle numbers for the four Al precursors with normal ALD process (shorter purging time). With increasing cycle number, higher Al content is observed, indicating that Al₂O₃ deposits on the ODTS/Si substrate. The increase of the Al content varies with the ALD precursor in a manner that corresponds with the trends seen in the decreasing rate of the WCA values (FIG. 2). For the Al(CH₃)ₓCl₃₋ₓ precursors, the Al content of the surface increases faster for precursors that have higher numbers of Cl ligands. Also, the precursor with longer alkyl ligands, Al(C₂H₅)₃, shows more efficient blocking compared to that with shorter ligands, Al(CH₃)₃. It is noteworthy that the Al content for the Al(C₂H₅)₃ precursor remains nearly zero for up to 75 cycles, behavior which is distinct from the others. In addition, differences between precursors were observed at 25 cycles by XPS (see FIG. 3A), whereas differences only start to show up after 50 cycles in the WCA analysis (see FIG. 2). Both measurements show the same trend, and the delay in the WCA measurement can be attributed to the macroscopic-scale nature of WCA.

Because the mechanism by which film nucleates during ALD on the non-growth surface (in this case, ODTS/Si) may differ from that on the growth surface (Si), it is important to reoptimize the process parameters with the non-growth surface in mind. In an exemplary aspect, this disclosure aims to find ALD process parameters that minimize Al₂O₃ deposition on ODTS/Si while maintaining good deposition on Si. There are several possible strategies, including: (i) decreasing the precursor exposure by tuning pressure and time and (ii) increasing precursor desorption by changing the growth temperature and by purging the surface. The decrease in precursor exposure was previously shown effective; however, minimal pressure and precursor dose time is already used. Also, the growth temperature is fixed at 200° C., which is where the ALD temperature windows overlap across the four different Al precursors.

FIG. 3B is a graphical representation of the amount of Al deposited on the SAM-coated surface as a function of purging time at a fixed cycle-number of 50 cycles. Increased purging time is explored here, and the results show that a gradual decrease in Al content occurs for the AlCl₃ and Al(CH₃)₂Cl precursors as purging time is increased. In contrast, no significant change for Al(CH₃)₃ is observed. In addition, the Al(C₂H₅)₃ precursor shows almost no growth on ODTS/Si even for 30 sec, which was also seen in FIG. 3A.

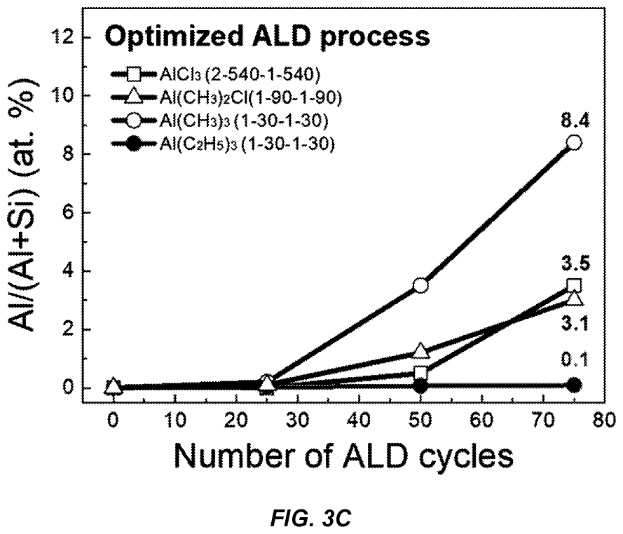

FIG. 4 is a graphical representation of growth per cycle of Al₂O₃ with Al(CH₃)ₓCl₃₋ₓ (x=0, 1, and 3) as a function of precursor purging time on Si. This shows that GPCs on the growth surface (Si) are the same under the conditions of FIG. 3B, i.e., they are independent of purging time in the long time regime. Thus, based on the results, the following ALD conditions are selected at which saturation is approached on the ODTS/Si surface (precursor exposure, purging, reactant exposure, and purging, each in a sec): 2-540-1-540 for AlCl₃, 1-90-1-90 for Al(CH₃)₂Cl, and 1-30-1-30 for Al(CH₃)₃ and Al(C₂H₅)₃.

The trends seen in FIGS. 3A and 3B can be understood in terms of the varying Lewis acidity across the Al precursor series. Because of the high electronegativity of the Cl ligand, the precursors become less Lewis acidic with a decreasing number of chlorine ligands in Al(CH₃)ₓCl₃₋ₓ. Lower Lewis acidity would lead to less favorable adsorption of alkyl precursors on the surface compared to that of halide precursors, resulting in a shorter required purging time. Under normal process conditions, the precursor molecules may adsorb on the SAMs, and unpurged molecules could react with subsequent exposure of the water coreactant, leading to Al₂O₃ nucleation, which has been observed in ALD on organic materials such as polymers.

Hence, AlCl₃, which has the highest Lewis acidity, is most likely to lead to unwanted Al₂O₃ nucleation if it is not fully purged away, consistent with the result shown in FIG. 3A. By extension, molecules that adsorb strongly on the SAMs are expected to require a longer purging time to be removed and should show the biggest decrease in unwanted Al₂O₃ growth when the purging time is increased. This hypothesis is supported by the results of FIG. 3B, in which the Al content was found to be greatly reduced for the Al(CH₃)₂Cl and AlCl₃ precursors in particular. However, the film growth by Al(CH₃)₃ is not entirely prevented, even when using a very long purging time (4.5% for 540 s of purging shown in FIG. 3B). This result suggests that a small amount of Al(CH₃)₃ irreversibly binds onto or within the SAMs and strongly resists removal by purging.

To further probe the role of Lewis acidity on the physisorption of the chloride precursors at the SAM-protected surface, and its role in unwanted Al₂O₃ nucleation, a comparative study is performed. ALD is carried out on a different substrate, Au, which is protected by an ODT SAM. The Au substrate was chosen because it is devoid of Lewis basic sites, unlike the native oxide of the Si substrate. In addition, the ODT/Au SAM system has been extensively studied and is known to form a well-packed monolayer.

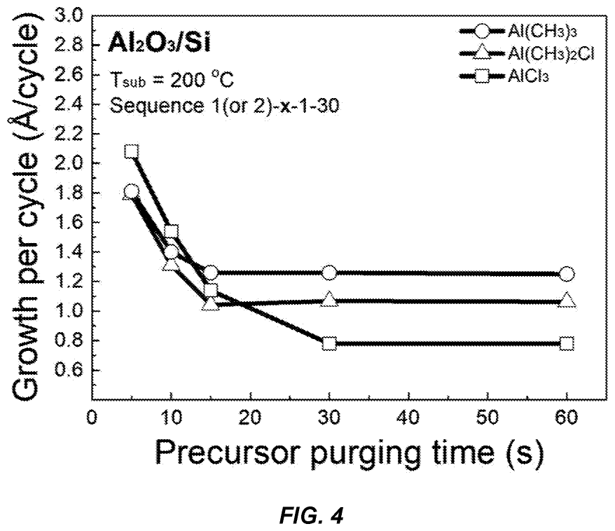

FIG. 5A is a graphical representation of Al atomic percentage defined as Al/(Al+Si) and Al/(Al+Au) for ALD from AlCl₃ on ODT/Au and ODTS/Si, respectively, with increasing ALD cycle number. FIG. 5B is a graphical representation of Al atomic percentage for ALD from Al(CH₃)₃ on ODT/Au and ODTS/Si with increasing ALD cycle number. FIG. 5A shows that AlCl₃ deposition reaches an Al atomic percentage of 81.1% on the ODTS/Si surface after 75 cycles compared to only 35.5% for deposition on ODT/Au. On the other hand, no significant difference is observed between these two substrates for Al(CH₃)₃ ALD (see FIG. 5B). The data indicate that the substrate effect is significant for the AlCl₃ precursor, but negligible for Al(CH₃)₃. Thus, the results imply that higher Al uptake during ALD from AlCl₃ on ODTS/Si is caused by the reaction of the chloride precursor with Si—O bonds at the Si interface because of their strong Lewis acidity of the Al in AlCl₃ arising from the high electronegativity and electron-withdrawing nature of the Cl ligands. Meanwhile, the adsorption of the AlCl₃ precursor is less favorable on the Au substrate because of the non-Lewis basic, and therefore relatively inert, Au substrate.

FIG. 3C is a graphical representation of the amount of Al deposited using the newly optimized conditions for ALD on the SAM-coated surface as a function of ALD cycle numbers for the four Al precursors. Notably, the results differ significantly from those collected under the Si-optimized conditions in FIG. 3A. The overall Al content is dramatically reduced, compared to the conditions before re-optimization (note the different y-axis scale). Interestingly, the Al(CH₃)ₓCl₃₋ₓ precursors show the opposite trend from what was previously observed in FIG. 3A.

The results under reoptimized conditions show that Al(CH₃)₃ is the least blocked precursor, while AlCl₃ and Al(CH₃)₂Cl exhibit similar Al content values at fixed ALD cycle numbers. In contrast, the results using Al(C_{y}H_{2y+1})₃ precursors show a similar trend to that in FIG. 3A, indicating that the deposition by precursors containing only alkyl ligands is not significantly affected by the change of purging time (FIG. 3B). This result suggests that the presence of chloride ligands on the Al precursor leads to higher precursor uptake (WCA in FIG. 2 and Al content in FIG. 3A) on the ODTS/Si surface unless sufficient time is provided to purge away the precursors.

The selectivity of each precursor at a certain cycle number is calculated by Equation 1:

$${S}_{x} = \frac{{R}_{g s} - {R}_{n s}}{{R}_{g s} + {R}_{n s}} \qquad Equation 1$$

where Sₓ is the selectivity after x ALD cycles, and R represents the atomic composition of the deposited material as a function of the substrate. Specifically, R_{gs} represents the atomic composition ratio of Al/(Al+Si) for the growth surface (GS), which in this case is Si, and Rₙₛ represents that for the nongrowth surface (NS), i.e., ODTS/Si. Here, R is serving as a proxy for coverage.

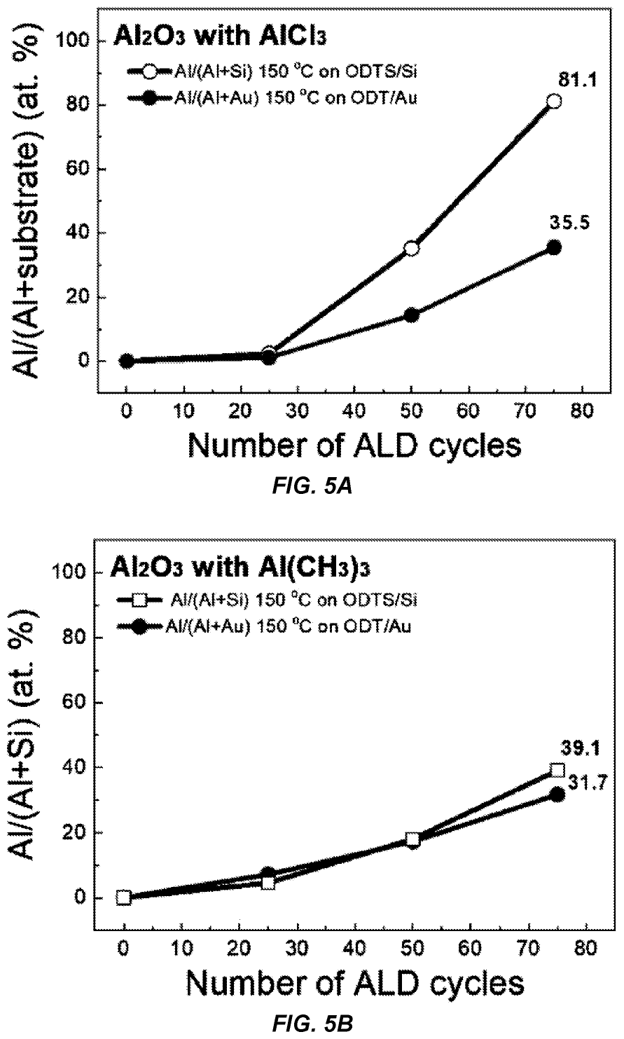

FIG. 6A is a graphical representation of the selectivity of Al₂O₃ALD on Si compared to that on the SAM-coated surface as a function of the number of ALD cycles. With an increasing number of ALD cycles, selectivity decreases, and, as expected, Al(CH₃)₃ shows the largest decrease in selectivity compared to the others. Al(C₂H₅)₃ shows a small decrease up to 75 cycles, but still maintains a high value of >0.98 selectivity, the highest of all the precursors studied. Also, since each precursor results in a different GPC of Al₂O₃, selectivity is replotted.

FIG. 6B is a graphical representation of the selectivity of Al₂O₃ALD replotted as a function of equivalent thickness on a Si surface (growth surface, GS). For example, 80, 60, 48, and 75 cycles are used for growing 6 nm of Al₂O₃ for AlCl₃, Al(CH₃)₂Cl, Al(CH₃)₃, and Al(C₂H₅)₃ precursors, respectively. As was shown in FIG. 6A, Al(CH₃)₃ has the lowest selectivity, while Al(C₂H₅)₃ has the highest. However, in contrast to FIG. 6A, Al(CH₃)₂Cl shows better selectivity than does AlCl₃ when the values are compared at the same equivalent thickness of ALD Al₂O₃ on Si, a result which is attributed to the higher GPC (and thus fewer ALD cycles needed) of Al(CH₃)₂Cl.

When the selectivity is benchmarked at 0.9, the selectivity trend (number of cycles at which this selectivity can be maintained) can be determined as follows: 25 cycles for Al(CH₃)₃ (˜3 nm), <50 cycles for AlCl₃ (˜4 nm), <60 cycles for Al(CH₃)₂Cl (˜6 nm), <100 cycles for Al(C₂H₅)₃ (˜8 nm). Note that the Al(C₂H₅)₃ precursor deposits selectively up to 8 nm with 0.9 of selectivity, whereas the commonly used Al precursor, Al(CH₃)₃ can maintain 0.9 of selectivity only up to 3 nm.

To understand what other forces beyond Lewis acidity may be driving the observed trends in precursor blocking by the SAMs, the precursor size and the role that dimerization will have on the average molecular size is next considered. Previous studies have found that when gaseous molecules penetrate deeply into small channels in a porous material, the degree of penetration correlates with the size of the molecules.

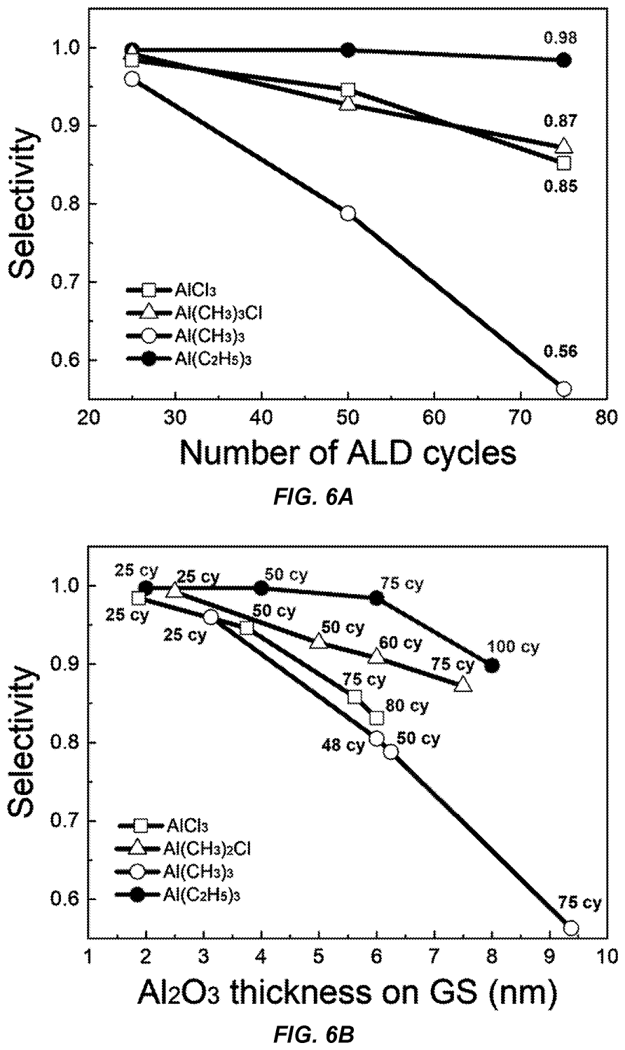

FIG. 7 is a graphical representation of the VDW volumes of the monomeric and dimeric structures of Al(CH₃)ₓCl₃₋ₓ (where x=0, 1, 2, and 3) and Al(C_{y}H_{2y+1})₃ (where y=1 and 2). The VDW sizes of all Al(CH₃)ₓCl₃₋ₓ precursors are similar when comparing monomers and dimers individually. With an increasing number of methyl ligands in Al(CH₃)ₓCl₃₋ₓ, the size increases, but the extent of change is small. On the other hand, the size of the Al(C₂H₅)₃ monomer and, by extension, the dimer are much larger than the sizes of all the others, attributed to the longer chain length of the ethyl ligands. It is noteworthy that the monomer size of Al(C₂H₅)₃ is not much smaller than the sizes of the dimers of the other precursors.

This series of precursors is known to be favorable for dimerization. For example, Al(CH₃)₃ forms a dimer in the vapor phase, and it was found that the degree of dimerization decreases with increasing temperature. Gas-phase dimers will dissociate at elevated temperatures by the following reactions:

Al₂(CH₃)₂ₓCl₆₋₂ₓ→2Al(CH₃)ₓCl₃₋ₓ

and

Al₂(C_{y}H_{2y+1})₆→2Al(C_{y}H_{2y+1})₃

Compared to that of Al(C_{y}H_{2y+1})₃, the dissociations of the AlCl₃ and Al(CH₃)₂Cl precursors are less favorable, which is attributed to a strong Lewis acid-base interaction of the Al center and the Cl ligand in the Cl-containing precursors.

The precursors described herein have different fractional concentrations of monomer and dimer molecules, indicated as Cₘₒₙₒₘₑᵣ and C_{dimer}. Given the relative Cₘₒₙₒₘₑᵣ and C_{dimer} values and the size of the precursors, the effective average size, V_{eff}, of precursor molecules can be calculated by Equation 2,

$${V}_{eff} = \frac{{C}_{m o n o m e r} {V}_{m o n o m e r} + {C}_{d i m e r} {V}_{d i m e r}}{{C}_{m o n o m e r} + {C}_{d i m e r}} \qquad Equation 2$$

where Vₘₒₙₒₘₑᵣ and V_{dimer} are the VDW sizes of the monomer and dimer in FIG. 7, respectively. Using Equation 2, the V_{eff} values of the example precursors are: AlCl₃ (143.7 Å³), AlCH₃Cl₂ (147.6 Å³), Al(CH₃)₂Cl (151.6 Å³), Cl(CH₃)₃ (87.2 Å³), and Al(C₂H₅)₃ (140.2 Å³).

The V_{eff} values are similar for all precursors except for Al(CH₃)₃, which is much smaller. The explanation can be understood by the combination of the dimer dissociation probability and the inherent molecular size. It is found that although the effective average sizes of the Al(CH₃)ₓCl₃₋ₓ monomers are similar, the dimer dissociation is much more favorable for Al(CH₃)₃ at 200° C., leading to a much smaller V_{eff} values of Al(CH₃)₃ compared to those of the other two. Regarding the Al(C_{y}H_{2y+1})₃ precursors, the energetics for both Al(CH₃)₃ and Al(C₂H₅)₃ are favorable for dimer dissociation, but the size of the Al(C₂H₅)₃ monomer is much larger than that of Al(CH₃)₃, leading to a larger value of V_{eff} for Al(C₂H₅)₃.

Overall, the higher Al content on ODTS/Si observed for Al(CH₃)₃ (see FIG. 3C) may be primarily attributed to its smaller size. Thus, although the physisorption of Al(CH₃)₃ onto the SAM is only weakly favorable, such that a relatively short purging time should remove physisorbed molecules on the surface (see FIG. 3B), the results indicate that the precursors adsorb on the SAMs and may penetrate into the SAMs where they start nucleation of Al₂O₃. This outcome can be explained by a more efficient diffusion of this precursor into the SAM because of its smallest relative size, primarily in the monomeric form, where it might reach the surface of Si—OH to form a stable chemical bond. In contrast, the AlCl₃ and Al(CH₃)₂Cl precursors may be more likely to physisorb near the surface of the SAMs, while resisting diffusion into the SAMs as dimerization increases their relative sizes. Because they are unlikely to penetrate the SAMs, they are thus more easily removed by purging. This suggestion is consistent with the steady decrease of Al content observed with increasing purging time (see FIG. 3B).

Meanwhile, the Al(C₂H₅)₃ precursor benefits from two favorable characteristics: (1) the larger size of Al(C₂H₅)₃ compared to that of Al(CH₃)₃ will inhibit its diffusion into the SAMs, whereas (2) its low Lewis acidity, inline with that of Al(CH₃)₃, makes its adsorption onto the SAM-coated surface relatively weak compared to that of the more strongly Lewis-acidic halide precursors. These characteristics correlate with the experimental results, indicating that Al(C₂H₅)₃ maintains a longer nucleation delay than either AlCl₃ or Al(CH₃)₂Cl, and that the amount of Al after 50 ALD cycles from Al(C₂H₅)₃ is almost 0 with only 30 s of purging time (see FIG. 3B). However, the growth inhibition of AlCl₃ and Al(CH₃)₂Cl does not last longer than that of the Al(C₂H₅)₃ precursors (see FIG. 3C), even though the effective molecular size of Al(C₂H₅)₃ is slightly smaller (see Table 1). These results support our proposed conclusion that precursor reactivity related to Lewis acidity (see FIG. 3B) plays a role in the selectivity, together with the precursor size.

Thus, the size of the precursor molecule is a dominant factor for blocking the adsorption of ALD precursors by SAMs, with the precursor reactivity (Lewis acidity) also playing a role in determining the blocking ability of the precursors. Moreover, this study suggests that dimerization correlates with precursor chemistry because chlorine precursors are more likely to dimerize than pure carbon precursors at ALD temperatures, and this fundamental finding translates to similar precursors. For example, AlCH₃Cl₂ will behave similarly to Al(CH₃)₂Cl and AlCl₃, and be less able to diffuse through the SAMs, increasing its effectiveness as a precursor for AS-ALD.

Finally, Al₂O₃ patterns are successfully fabricated on a Pt/SiO₂ pattern substrate by using the Al(C₂H₅)₃ precursor. This precursor is chosen because of its outstanding blocking ability (see FIGS. 6A and 6B) and this Pt/SiO₂ substrate because Pt has shown great selectivity for ODTS adsorption toward the SiO₂ surface. Fifty cycles of ALD with Al(C₂H₅)₃ are employed on ODTS-treated Pt/SiO₂ patterns.

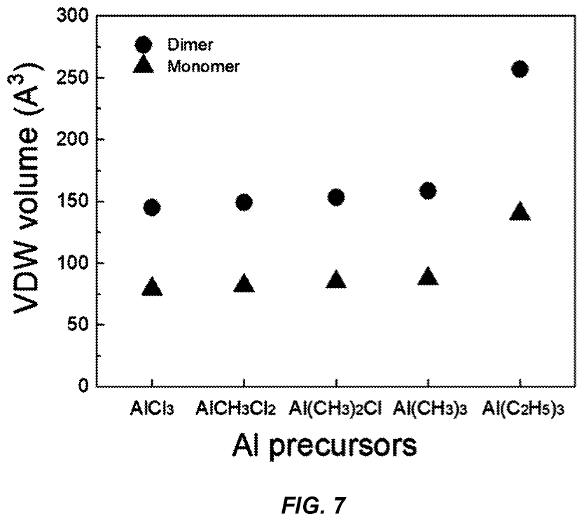

FIG. 8A is an SEM image of an Al₂O₃ pattern fabricated by 50 cycles of AS-ALD on an ODTS-treated Pt/SiO₂ substrate. FIG. 8B is a graphical representation of elemental line spectra for carbon, silicon, aluminum, and platinum along the vertical dashed line of FIG. 8A. This data clearly shows that the Al signal is detected mainly on the Pt area of the pattern. The selectivity of Al₂O₃ is calculated from the relative intensity ratio of the average Al signal in the Pt region and in the SiO₂ regions by using Equation 1, yielding a value of −0.95. Note that this value is comparable to the selectivity obtained by XPS for 50 ALD cycles with Al(C₂H₅)₃ on the SiO₂ versus ODTS-SiO₂ surface substrates, which is about 0.98.

FIG. 8C is an elemental mapping of AES for C in the Al₂O₃ pattern on the ODTS-treated Pt/SiO₂ of FIG. 8A. FIG. 8D is an elemental mapping of AES for Si in the Al₂O₃ pattern on the ODTS-treated Pt/SiO₂ of FIG. 8A. FIG. 8E is an elemental mapping of AES for Al in the Al₂O₃ pattern on the ODTS-treated Pt/SiO₂ of FIG. 8A. FIG. 8F is an elemental mapping of AES for Pt in the Al₂O₃ pattern on the ODTS-treated Pt/SiO₂ of FIG. 8A. These images show that Al₂O₃ films are selectively deposited, generating Al₂O₃ patterns that map onto the Pt patterns.

IV. Processes for Selective ALD

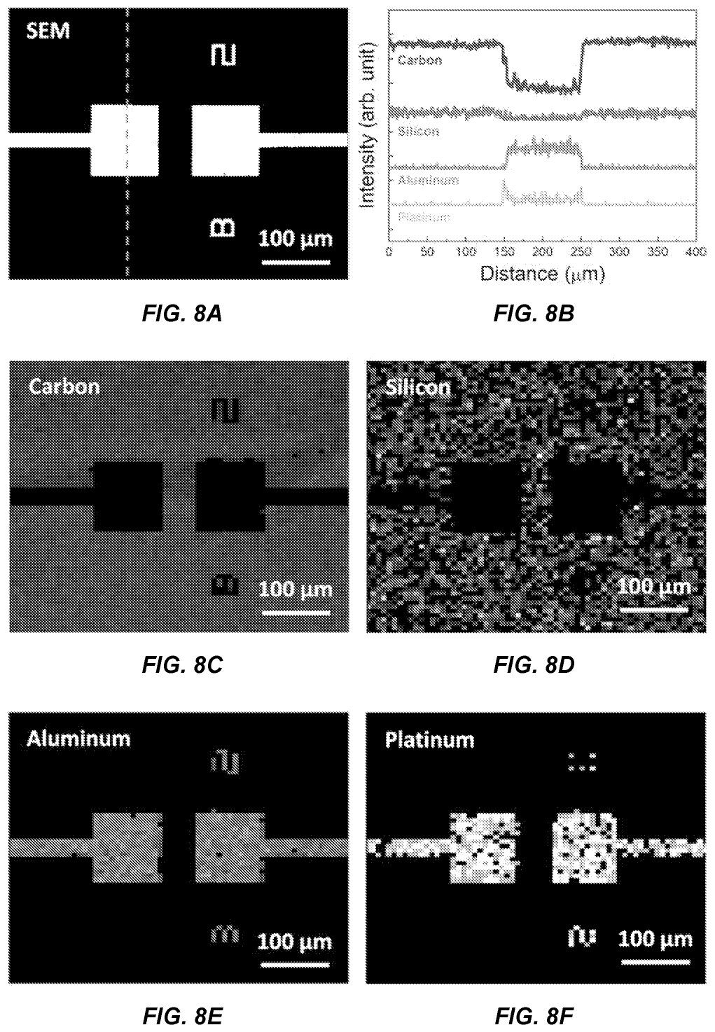

FIG. 9 is a flow diagram illustrating a process for selective ALD. The process optionally begins at operation 900, with depositing an SAM over a substrate to pattern for selective ALD. The process continues at operation 902, with applying an ALD precursor to the substrate, wherein an effective average molecule size (V_{eff}) of the ALD precursor is greater than 100 Å³. In an exemplary aspect, the V_{eff} of the ALD precursor is between 100 Å³ and 300 Å³, between 120 Å³ and 260 Å³, or between 130 Å³ and 200 Å³. The process continues at operation 904, with performing the selective ALD of a deposition material over the substrate. In an exemplary aspect, the selective ALD is performed using one or more process parameters (e.g., growth temperature, precursor partial pressure, precursor dosing time, purging time, reactant dosing time, or number of cycles) optimized to the ALD precursor.

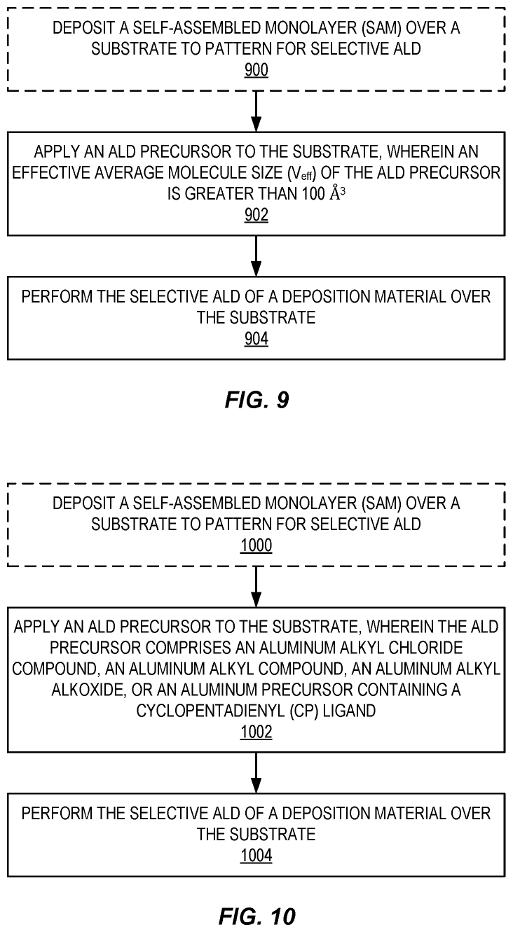

FIG. 10 is a flow diagram illustrating another process for selective ALD. The process optionally begins at operation 1000, with depositing an SAM over a substrate to pattern for selective ALD. The process continues at operation 1002, with applying an ALD precursor to the substrate, wherein the ALD precursor comprises an aluminum alkyl chloride compound (Al(C_{y}H_{2y+1})ₓCl₃₋ₓ, where 0≤x≤2 and y≥1), an aluminum alkyl compound (Al(C_{y}H_{2y+1})₃, where y≥2), an aluminum alkyl alkoxide (Al(CₙH₂ₙ₊₁)₃₋ₓ(OC_{z}H_{2z+1})ₓ, where 1≤x≤3, z≥2, and n≥1), or an aluminum precursor containing a cyclopentadienyl (Cp) ligand. The process continues at operation 1004, with performing the selective ALD of a deposition material over the substrate.

Although the operations of FIGS. 9 and 10 are illustrated in a series, this is for illustrative purposes and the operations are not necessarily order dependent. Some operations may be performed in a different order than that presented. Further, processes within the scope of this disclosure may include fewer or more steps than those illustrated in FIGS. 9 and 10.

Those skilled in the art will recognize improvements and modifications to the preferred embodiments of the present disclosure. All such improvements and modifications are considered within the scope of the concepts disclosed herein and the claims that follow.

What is claimed is:

1. A method for selective atomic layer deposition (ALD), the method comprising:
applying an ALD precursor to a substrate, wherein an effective average molecule size (V_{eff}) of the ALD precursor is greater than 100 cubic angstroms (Å³) and effective average molecule size is defined as
$${V}_{eff} = \frac{{C}_{m o n o m e r} {V}_{m o n o m e r} + {C}_{d i m e r} {V}_{d i m e r}}{{C}_{m o n o m e r} + {C}_{d i m e r}}$$
where Cₘₒₙₒₘₑᵣ is a fractional concentration of a monomer of the ALD precursor, C_{dimer} is a fractional concentration of a dimer of the ALD precursor, Vₘₒₙₒₘₑᵣ is a van der Waal (VDW) size of the monomer, and V_{dimer} is a VDW size of the dimer; and
performing selective ALD of a deposition material over the substrate.

2. The method of claim 1, wherein the V_{eff} of the ALD precursor is between 100 Å³ and 300 Å³.

3. The method of claim 2, wherein the V_{eff} of the ALD precursor is between 120 Å³ and 260 Å³.

4. The method of claim 3, wherein the V_{eff} of the ALD precursor is between 130 Å³ and 200 Å³.

5. The method of claim 1, wherein the deposition material comprises one or more of a metal chalcogenide, a metal pnictide, a metal halide, or a metal-group 14 compound.

6. The method of claim 1, wherein performing selective ALD of the deposition material over the substrate comprises using one or more process parameters optimized to the ALD precursor.

7. The method of claim 6, wherein the one or more process parameters optimized to the ALD precursor comprise one or more of growth temperature, precursor partial pressure, precursor dosing time, precursor dosing pressure, purging time, reactant dosing time, reactant dosing pressure, and number of cycles.

8. The method of claim 7, wherein performing selective ALD of aluminum oxide (Al₂O₃) over the substrate using the one or more process parameters comprises decreasing the precursor partial pressure or precursor dosing time to improve selectivity of the ALD.

9. The method of claim 7, wherein performing selective ALD of aluminum oxide (Al₂O₃) over the substrate using the one or more process parameters comprises increasing the purging time or purging pressure to improve selectivity of the ALD.

10. The method of claim 7, wherein performing selective ALD of aluminum oxide (Al₂O₃) over the substrate using the one or more process parameters comprises decreasing the growth temperature to improve selectivity of the ALD.

11. The method of claim 1, further comprising depositing a self-assembled monolayer (SAM) over the substrate to pattern for the selective ALD.

12. A method for selective atomic layer deposition (ALD), the method comprising:
applying an ALD precursor to a substrate, wherein the ALD precursor comprises an aluminum alkyl chloride compound (Al(C_{y}H_{2y+1})ₓCl₃₋ₓ, where 0≤x≤2 and y≥1), an aluminum alkyl compound (Al(C_{y}H_{2y+1})₃, where y≥2), an aluminum alkyl alkoxide (Al(CₙH₂ₙ₊₁)₃₋ₓ(OC_{z}H_{2z+1})ₓ, where 1≤x≤3, z≥2, and n≥1), or an aluminum precursor containing a cyclopentadienyl (Cp) ligand; and
performing selective ALD of a deposition material over the substrate.

13. The method of claim 12, wherein the deposition material comprises at least one of a metal chalcogenide, a metal pnictide, a metal halide, or a metal-group 14 compound.

14. The method of claim 13, wherein the deposition material comprises aluminum oxide (Al₂O₃).

15. The method of claim 12, wherein performing selective ALD of the deposition material over the substrate comprises using one or more process parameters optimized to the ALD precursor, the one or more process parameters comprising one or more of growth temperature, precursor partial pressure, precursor dosing time, purging time, purging pressure, reactant dosing time, reactant dosing pressure, and number of cycles.

16. The method of claim 15, wherein performing selective ALD of the deposition material over the substrate using the one or more process parameters comprises:
decreasing the precursor partial pressure;
decreasing the precursor dosing time;
increasing the purging time;
increasing the purging pressure;
decreasing the reactant dosing time;
decreasing the reactant dosing pressure; and
decreasing the growth temperature.

17. The method of claim 16, wherein performing selective ALD of the deposition material over the substrate using the one or more process parameters comprises using the purging time between 1 and 540 seconds.

18. The method of claim 12, wherein the substrate comprises silicon (Si).

19. The method of claim 18, further comprising depositing a self-assembled monolayer (SAM) over the substrate to pattern for the selective ALD.

20. The method of claim 19, wherein the substrate comprises at least one of a metal or a dielectric and the SAM comprises one or more of an organosilicon compound, an organosulfur compound, an alkyl compound, a phosphonic acid compound, or a polymer compound.
